(19) United States
(12) Patent Application Publication
(10) Pub. No.: US 2025/0006088 A1
(43) Pub. Date: Jan. 2, 2025

(54) DEVICE FOR TESTING ELEMENTS OF DISPLAY PANEL

(71) Applicant: Samsung Display Co., LTD., Yongin-si (KR)

(72) Inventors: Pong Ok PARK, Yongin-si (KR); Ki Young YOON, Yongin-si (KR); Jae Bong YANG, Yongin-si (KR); Seung Hyeok IM, Yongin-si (KR)

(21) Appl. No.: 18/584,927

(22) Filed: Feb. 22, 2024

(30) Foreign Application Priority Data
Jun. 30, 2023 (KR) 10-2023-0084965

(51) Int. Cl. G09G 3/00

(52) U.S. Cl. CPC G09G 3/006; G09G 2330/12

(57) ABSTRACT

The present disclosure relates to a device for testing elements of a display panel. According to one or more embodiments of the disclosure, an element test device includes a display panel on which electrical elements including thin-film transistors are located, a test panel that extends from the display panel or is integral with the display panel, and on which test electrical elements are located through a same manufacturing process as the electrical elements, and a test signal processor configured to substantially simultaneously supply a first driving voltage and a second driving voltage to the test electrical elements using a first channel and a second channel, respectively, and to detect electrical output characteristics of the test electrical elements using a number of k channels equal to a number of the test electrical elements.

### CROSS-REFERENCE TO RELATED APPLICATION

The present application claims priority to, and the benefit of, Korean Patent Application No. 10-2023-0084965, filed on Jun. 30, 2023, in the Korean Intellectual Property Office, the entire disclosure of which is incorporated herein by reference.

### BACKGROUND

### 1. Field

The present disclosure relates to a device for testing elements of a display panel.

### 2. Description of the Related Art

As the information society develops, demands for display devices for displaying images are increasing in various forms. For example, display devices are applied to various electronic devices, such as smartphones, digital cameras, notebook computers, navigation devices, and smart televisions.

The display devices may be flat panel display devices, such as liquid crystal display devices, field emission display devices, and organic light-emitting display devices. Among these flat panel display devices, a light-emitting display device includes a light-emitting element that enables each pixel of a display panel to emit light by itself. Thus, the light-emitting display device can display an image without a backlight unit that provides light to the display panel.

Display panels are manufactured by forming pixels, driving circuits, etc. in cell areas of mother glass according to resolution and separating and modularizing the cell areas. In a state before each display panel is made into a product, electrical characteristics of electrical elements, such as thin-film transistors formed on the display panel cannot be directly tested.

To test and check the electrical characteristics of the electrical elements formed on the display panels, test electrical elements may be formed on test panels respectively extending from the cell areas, that is, the display panels through the same manufacturing process as the electrical elements of the display panels. Accordingly, after a display panel and a test panel are separated together from the mother glass, it is possible to check the characteristics of the electrical elements formed on the display panel by detecting the electrical characteristics of the test electrical elements formed on the test panel.

### SUMMARY

Aspects of the present disclosure provide a device for testing elements of a display panel by concurrently or substantially simultaneously supplying driving voltages to test elements of a test panel and by detecting output signals of the test elements by using a reduced (e.g., minimum) number of contact pins and channels.

However, aspects of the present disclosure are not restricted to the one set forth herein. The above and other aspects of the present disclosure will become more apparent to one of ordinary skill in the art to which the present disclosure pertains by referencing the detailed description of the present disclosure given below.

According to one or more embodiments of the disclosure, an element test device includes a display panel on which electrical elements including thin-film transistors are located, a test panel that extends from the display panel or is integral with the display panel, and on which test electrical elements are located through a same manufacturing process as the electrical elements, and a test signal processor configured to substantially simultaneously supply a first driving voltage and a second driving voltage to the test electrical elements using a first channel and a second channel, respectively, and to detect electrical output characteristics of the test electrical elements using a number of k channels equal to a number of the test electrical elements.

The element test device may further include a loader for receiving the display panel and the test panel, a power supply configured to generate the first driving voltage and the second driving voltage to be supplied to the test electrical elements, and a contact terminal unit including contact terminals respectively contacting first electrodes, second electrodes, and third electrodes of the test electrical elements.

The test signal processor may be configured to substantially simultaneously supply the first driving voltage to the first electrodes of the test electrical elements through a first channel line of the contact terminal unit, to substantially simultaneously supply the second driving voltage to the second electrodes of the test electrical elements through a second channel line of the contact terminal unit, and to detect electrical characteristics including voltages and current amounts of electrical signals respectively output from the third electrodes of the test electrical elements through k channel lines and the k channels of the contact terminal unit.

The contact terminals may include first electrode contact terminals respectively contacting the first electrodes of the test electrical elements, second electrode contact terminals respectively contacting the second electrodes of the test electrical elements, and third electrode contact terminals respectively contacting the third electrodes of the test electrical elements.

The contact terminal unit may further include a first channel line connecting the first electrode contact terminals to one first channel in a parallel structure, a second channel line connecting the second electrode contact terminals to one second channel in a parallel structure, and k channel lines connecting the third electrode contact terminals to the k channels in a one-to-one manner.

The test signal processor, during a first period, may be configured to supply the first driving voltage having a first voltage level to the first channel line, to supply the second driving voltage having a gradually varying voltage level to the second channel line, and to detect electrical signals respectively output from the third electrodes of the test electrical elements through the k channel lines, and, during a second period, may be configured to supply the first driving voltage having a second voltage level that is different from the first voltage level to the first channel line, to supply the second driving voltage having a gradually varying voltage level to the second channel line, and to detect electrical signals respectively output from the third electrodes of the test electrical elements through the k channel lines.

The test signal processor may include a source voltage supply configured to alternately generate a first driving voltage of about 0.1 V and a first driving voltage of about 5.1 V during the first period and the second period, respectively, a gate voltage supply configured to generate the second driving voltage that gradually varies from about 8.0 V to about −13 V by about 0.25 V, or that gradually varies from about −15 V to about 15V by about 0.25 V, and a voltage supply control configured to control the source voltage supply to output the first driving voltage of about 0.1 V to the first channel line during the first period, to control the source voltage supply to output the first driving voltage of about 5.1 V to the first channel line during the second period, and to control the gate voltage supply to output the second driving voltage to the second channel line during the first period and the second period.

The contact terminals may include four first electrode contact terminals respectively contacting first electrodes of first through fourth thin-film transistors among the test electrical elements, four second electrode contact terminals respectively contacting second electrodes of the first through fourth thin-film transistors, and four third electrode contact terminals respectively contacting third electrodes of the first through fourth thin-film transistors.

The contact terminal unit may further include a first channel line connecting the four first electrode contact terminals to one first channel in a parallel structure, a second channel line connecting the four second electrode contact terminals to one second channel in a parallel structure, and k channel lines connecting the four third electrode contact terminals to the k channels in a one-to-one manner.

According to one or more embodiments of the disclosure, an element test device includes a display panel on which electrical elements including thin-film transistors are located, a test panel that extends from the display panel or is integral with the display panel, and on which test electrical elements are located through a same manufacturing process as the electrical elements, a loader configured to receive the display panel and the test panel, a power supply configured to generate a first driving voltage and a second driving voltage to be supplied to the test electrical elements, a contact terminal unit including contact terminals respectively contacting first electrodes, second electrodes, and third electrodes of the test electrical elements, and a test signal processor configured to substantially simultaneously supply the first driving voltage and the second driving voltage to the test electrical elements using a first channel and a second channel, respectively, and to detect electrical output characteristics of the test electrical elements using a number of k channels equal to the number of the test electrical elements.

The test signal processor may be configured to substantially simultaneously supply the first driving voltage to the first electrodes of the test electrical elements through a first channel line of the contact terminal unit, to substantially simultaneously supply the second driving voltage to the second electrodes of the test electrical elements through a second channel line of the contact terminal unit, and to detect electrical characteristics including voltages and current amounts of electrical signals respectively output from the third electrodes of the test electrical elements through k channel lines and the k channels of the contact terminal unit.

The contact terminals may include first electrode contact terminals respectively contacting the first electrodes of the test electrical elements, second electrode contact terminals respectively contacting the second electrodes of the test electrical elements, and third electrode contact terminals respectively contacting the third electrodes of the test electrical elements.

The contact terminal unit may further include a first channel line connecting the first electrode contact terminals to one first channel in a parallel structure, a second channel line connecting the second electrode contact terminals to one second channel in a parallel structure, and k channel lines connecting the third electrode contact terminals to the k channels in a one-to-one manner.

The test signal processor, during a first period, may be configured to supply the first driving voltage having a first voltage level to the first channel line, to supply the second driving voltage having a gradually varying voltage level to the second channel line, and to detect electrical signals respectively output from the third electrodes of the test electrical elements through the k channel lines, and, during a second period, may be configured to supply the first driving voltage having a second voltage level that is different from the first voltage level to the first channel line, to supply the second driving voltage having a gradually varying voltage level to the second channel line, and to detect electrical signals respectively output from the third electrodes of the test electrical elements through the k channel lines.

The contact terminals may include four first electrode contact terminals respectively contacting first electrodes of first through fourth thin-film transistors among the test electrical elements, four second electrode contact terminals respectively contacting second electrodes of the first through fourth thin-film transistors, and four third electrode contact terminals respectively contacting third electrodes of the first through fourth thin-film transistors.

The contact terminal unit may further include a first channel line connecting the four first electrode contact terminals to one first channel in a parallel structure, a second channel line connecting the four second electrode contact terminals to one second channel in a parallel structure, and k channel lines connecting the four third electrode contact terminals to the k channels in a one-to-one manner.

A device for testing elements of a display panel according to one or more embodiments of the present disclosure can concurrently or substantially simultaneously detect and check electrical characteristics of a plurality of test elements using a reduced (e.g., minimum) number of channels and connection pins. Accordingly, it is possible to quickly test element characteristics of a test panel and a display panel and reduce the overall test period.

In addition, the device for testing elements of a display panel according to one or more embodiments can improve the efficiency of testing element characteristics of a display panel by concurrently or substantially simultaneously detecting electrical characteristics of a plurality of test elements formed on a test panel on a group-by-group basis.

However, the aspects of the present disclosure are not restricted to the one set forth herein. The above and other aspects of the present disclosure will become more apparent to one of daily skill in the art to which the present disclosure pertains by referencing the claims.

### BRIEF DESCRIPTION OF DRAWINGS

These and/or other aspects will become apparent and more readily appreciated from the following description of the embodiments, taken in conjunction with the accompanying drawings in which:

FIG. 1 is a configuration diagram illustrating display panels and test panels separated on mother glass;

FIG. 2 is a configuration block diagram illustrating any one display panel and a test panel of FIG. 1 in detail;

FIG. 3 is a configuration block diagram illustrating the arrangement structure of thin-film transistors formed on the test panel of FIG. 2;

FIG. 4 is a configuration block diagram illustrating the arrangement structure of thin-film transistors and other electrical elements formed on the test panel of FIG. 2;

FIG. 5 is a configuration diagram illustrating a device for testing elements of a display panel and a process of testing a test panel according to one or more embodiments;

FIG. 6 is a detailed block diagram illustrating each component of the device for testing elements of a display panel according to one or more embodiments;

FIG. 7 is a configuration diagram illustrating, in detail, the channel contact structure of a contact terminal unit illustrated in FIG. 6;

FIG. 8 is a monitoring screen showing a test panel testing sequence according to one or more embodiments;

FIG. 9 is a graph illustrating the change in output current detected from thin-film transistors of a test panel; and

FIG. 10 is a table showing a change in time suitable to test a test panel according to one or more embodiments.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure. The present disclosure covers all modifications, equivalents, and replacements within the idea and technical scope of the present disclosure. Further, each of the features of the various embodiments of the present disclosure may be combined with each other, in part or in whole, and technically various interlocking and driving are possible. Each embodiment may be implemented independently of each other or may be implemented together in an association.

It will be understood that when an element, layer, region, or component is referred to as being “formed on,” “on,” “connected to,” or “(operatively or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a resistor, a capacitor, and/or the like. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XYY, YZ, and ZZ, or any variation thereof. Similarly, the expression such as “at least one of A and B” and “at least one of A or B” may include A, B, or A and B. As used herein, “or” generally means “and/or,” and the term “and/or” includes any and all combinations of one or more of the associated listed items. For example, the expression such as “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are used only used to distinguish one element, member, component, region, area, layer, section, or portion from another element, member, component, region, area, layer, section, or portion. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

As used herein, the term “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/−5% of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.”

In some embodiments well-known structures and devices may be described in the accompanying drawings in relation to one or more functional blocks (e.g., block diagrams), units, and/or modules to avoid unnecessarily obscuring various embodiments. Those skilled in the art will understand that such block, unit, and/or module are/is physically implemented by a logic circuit, an individual component, a microprocessor, a hard wire circuit, a memory element, a line connection, and other electronic circuits. This may be formed using a semiconductor-based manufacturing technique or other manufacturing techniques. The block, unit, and/or module implemented by a microprocessor or other similar hardware may be programmed and controlled using software to perform various functions discussed herein, optionally may be driven by firmware and/or software. In addition, each block, unit, and/or module may be implemented by dedicated hardware, or a combination of dedicated hardware that performs some functions and a processor (for example, one or more programmed microprocessors and related circuits) that performs a function different from those of the dedicated hardware. In addition, in some embodiments, the block, unit, and/or module may be physically separated into two or more interact individual blocks, units, and/or modules without departing from the scope of the present disclosure. In addition, in some embodiments, the block, unit and/or module may be physically combined into more complex blocks, units, and/or modules without departing from the scope of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

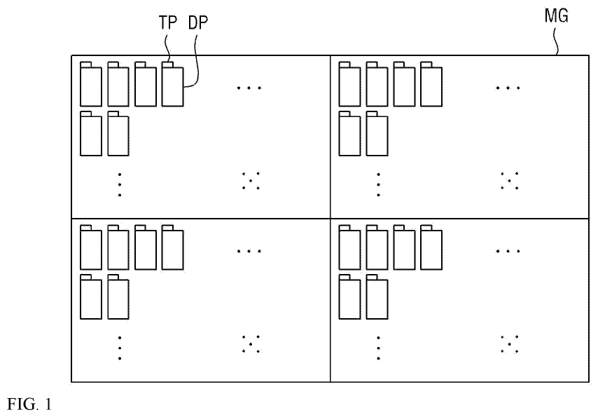

FIG. 1 is a configuration diagram illustrating display panels DP and test panels TP separated on mother glass MG.

Referring to FIG. 1, a plurality of areas that can be suitably separated may be set in the mother glass MG, and cell areas to be manufactured into a plurality of display panels DP are defined in the mother glass MG. Here, the cell areas of the mother glass MG are separated to form the display panels DP, respectively. For example, the display panels DP may be manufactured by forming pixels, integrated circuits, etc. in the cell areas of the mother glass MG according a resolution (e.g., preset resolution) and separating and modularizing the cell areas. A driving circuit in the form of a microprocessor may be additionally formed on each display panel DP.

As described above, in a state before each modularized display panel DP is made into a product, electrical elements, such as thin-film transistors, resistors, and capacitors formed on the display panel DP, cannot be physically contacted. There is a risk of damage to the display panel DP or the electrical elements in the process of physical contact. Accordingly, electrical characteristics, such as input/output voltages or currents of electrical elements (e.g., thin-film transistors) formed on each display panel DP, cannot be directly tested through physical contact.

To test and check the electrical characteristics of the electrical elements formed on the display panels DP, test electrical elements are formed on test panels TP respectively extending from the display panels DP through the same manufacturing process as the electrical elements of the display panels DP. Here, the test panels TP may extend from the display panels DP, or may be integrally formed with the display panels DP, respectively. The test electrical elements are formed on a front surface of each test panel TP through the same manufacturing process as the electrical elements of each display panel DP. The electrical elements of each display panel DP, and the test electrical elements of each test panel TP, are formed at the same time through the same process. The electrical elements of each display panel DP and the test electrical elements of each test panel TP may include a plurality of thin-film transistors, a plurality of resistors, and a plurality of capacitors. An example of testing the electrical characteristics of the thin-film transistors among the test electrical elements will be described below. That is, the electrical elements or the test electrical elements are not limited to the thin-film transistors.

To detect and test the electrical characteristics of the thin-film transistors formed on each display panel DP, a display panel DP and a test panel TP separated from the mother glass MG are placed on an element test device. Then, the electrical characteristics of thin-film transistors formed on the display panel DP may be checked by detecting and testing the electrical characteristics of test thin-film transistors formed on the test panel TP.

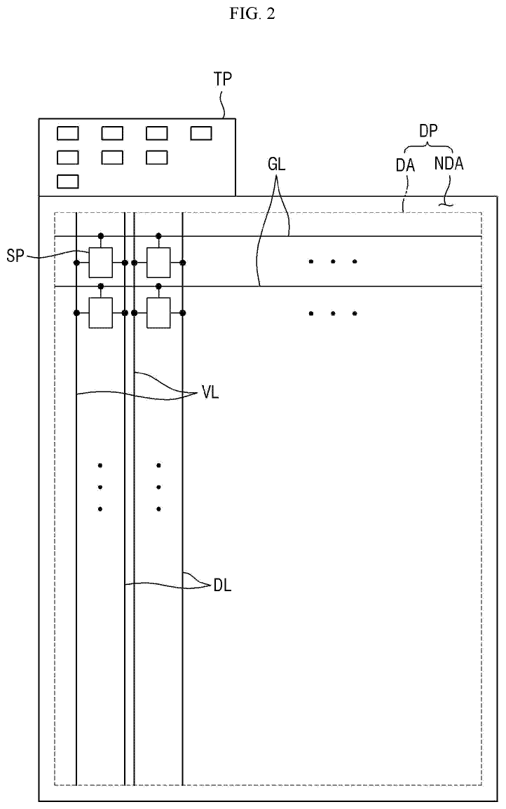

FIG. 2 is a configuration block diagram illustrating any one display panel DP and a test panel TP of FIG. 1 in detail.

Referring to FIG. 2, a display area DA and a non-display area NDA are defined in the display panel DP. The display area DA is an area for displaying an image, and may be defined as a central area of the display panel DP. The display area DA may include a plurality of pixels SP, a plurality of gate lines GL, a plurality of data lines DL, and a plurality of power lines VL.

The pixels SP are respectively located at crossing regions of the gate lines GL extending parallel to each other in an X-axis direction, and the data lines DL extending parallel to each other in a Y-axis direction. Here, each of the pixels SP may be defined as a minimum unit that outputs light for displaying an image. Each of the pixels SP includes at least one light-emitting element that emits light, and at least one thin-film transistor for applying a driving current to the at least one light-emitting element. In addition, at least one capacitor may be further formed in each of the pixels SP.

In a manufacturing process for forming thin-film transistors in each of the cell areas separated to form the display panels DP, respectively, test thin-film transistors are also formed on the test panel TP through the same manufacturing process as those of each display panel DP. Accordingly, the test thin-film transistors formed on the test panel TP have the same electrical characteristics as the thin-film transistors formed on each display panel DP.

The gate lines GL supply gate signals received from a separate gate-driving integrated circuit to the pixels SP. The gate lines GL may extend in the X-axis direction, and may be spaced apart from each other in the Y-axis direction crossing the X-axis direction.

The data lines DL may supply data voltages received from a separate display driving circuit to the pixels SP. The data lines DL may extend in the Y-axis direction, and may be spaced apart from each other in the X-axis direction.

The power lines VL may supply a power supply voltage received from a power supply (e.g., power supply unit) or the display driving circuit to the pixels SP. Here, the power supply voltage may be at least one of a driving voltage, an initialization voltage, and a reference voltage. The power lines VL may extend in the Y-axis direction, and may be spaced apart from each other in the X-axis direction.

The non-display area NDA may surround the display area DA (e.g., in plan view). The gate-driving integrated circuit, fan-out lines, gate control lines, and the like are formed in the non-display area NDA.

The gate-driving integrated circuit formed in the non-display area NDA may generate a plurality of gate signals based on a gate control signal received from the display driving circuit or the like. Then, the gate signals may be sequentially supplied to the gate lines GL according to a set order.

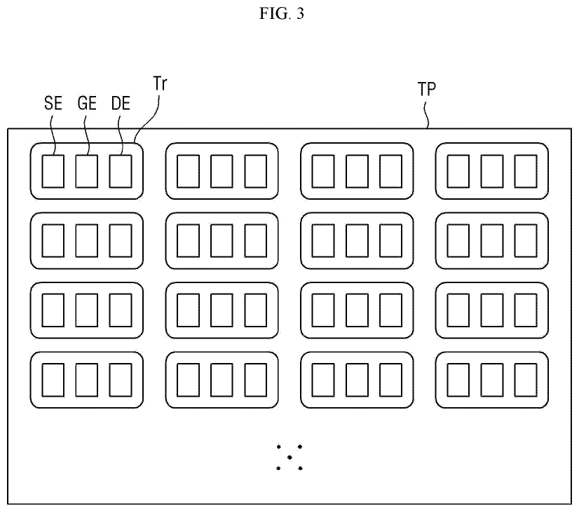

FIG. 3 is a configuration block diagram illustrating the arrangement structure of thin-film transistors formed on the test panel TP of FIG. 2.

Referring to FIG. 3, test thin-film transistors Tr are formed on the test panel TP through the same manufacturing process as the thin-film transistors of each display panel DP. The test thin-film transistors Tr formed on the test panel TP have the same electrical characteristics as the thin-film transistors of the pixels SP formed on each display panel DP. Each of the test thin-film transistors Tr includes a first electrode SE (e.g., a source electrode), a second electrode GE (e.g., a gate electrode), and a third electrode DE (e.g., a drain electrode) exposed on the surface so that they can be physically contacted.

The test thin-film transistors Tr formed on the test panel TP may be formed and located side by side in a vertical or horizontal direction. In addition, the test thin-film transistors Tr may be formed and located at equal intervals. For example, the test thin-film transistors Tr may be formed and located in any one of 1×2, 1×4, 2×2, 2×4, 4×4, . . . n×m arrays (n and m being positive integers that are the same or that are different from each other).

The test thin-film transistors Tr may be formed and located in a 2×4 or 4×4 array, and may form groups of four test thin-film transistors Tr adjacent to each other in the horizontal or vertical direction. Electrical characteristics of every four test thin-film transistors Tr located side by side in the horizontal or vertical direction may be concurrently or substantially simultaneously tested. An example of concurrently or substantially simultaneously testing the electrical characteristics of every four test thin-film transistors Tr arranged side by side in the horizontal direction of FIG. 3 will be described below. The arrangement structure and number of test thin-film transistors Tr tested concurrently or substantially simultaneously are not limited to the embodiments described below and may be variously modified.

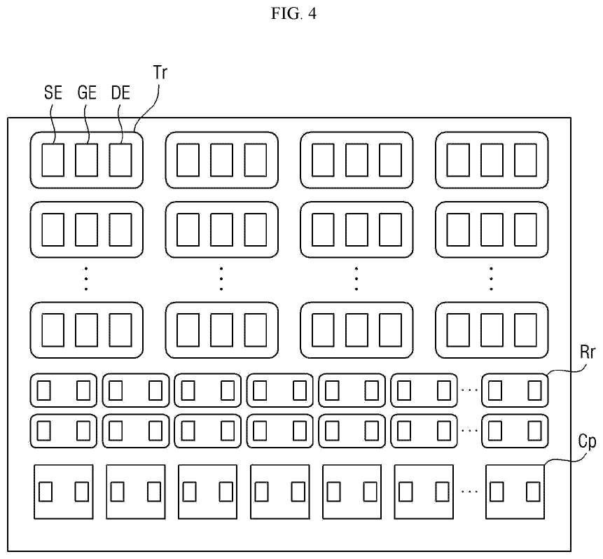

FIG. 4 is a configuration block diagram illustrating the arrangement structure of thin-film transistors and other electrical elements formed on the test panel TP of FIG. 2.

Referring to FIG. 4, test thin-film transistors Tr may be formed and located side by side on the test panel TP in the vertical or horizontal direction. The test thin-film transistors Tr may be formed and located in an n×m array, such as 2×2 or 2×4. For example, the test thin-film transistors Tr may be formed and located in a 2×4 array. Electrical characteristics of every four test thin-film transistors Tr arranged side by side in the horizontal direction may be concurrently or substantially simultaneously tested using a separate element test device.

In addition, test resistors Rr, which may be formed at the same time through the same manufacturing process as resistors formed on each display panel DP, may be further located on the test panel TP. The test resistors Rr may be formed and located in areas that are different from areas where the test thin-film transistors Tr are formed. For example, the test resistors Rr may be formed and located in an n×m array, such as 2×2 or 2×4. For example, the test resistors Rr may be formed and located in a 2×10 array. Electrical characteristics of every ten test resistors Rr arranged side by side in the horizontal direction may be concurrently or substantially simultaneously tested using the separate element test device.

Test capacitors Cp, which may be formed at the same time through the same manufacturing process as capacitors formed on each display panel DP, may be further located on the test panel TP. The test capacitors Cp may be formed and located in areas that are different from the areas where the test thin-film transistors Tr and the test resistors Rr are formed. For example, the test capacitors Cp may be formed and located in an n×m array, such as 1×2 or 2×4. For example, the test resistors Rr may be formed and located in a 1×10 array. Electrical characteristics of every ten test capacitors Cp arranged side by side in the horizontal direction may be concurrently or substantially simultaneously tested using the separate element test device.

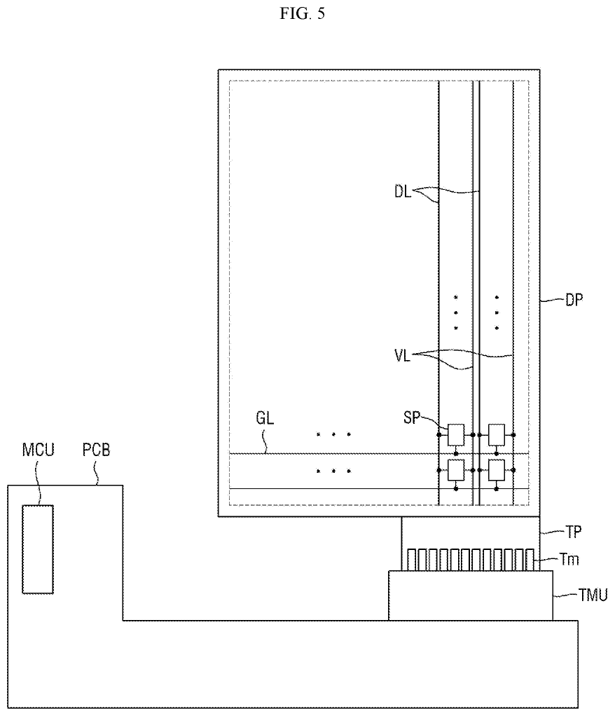

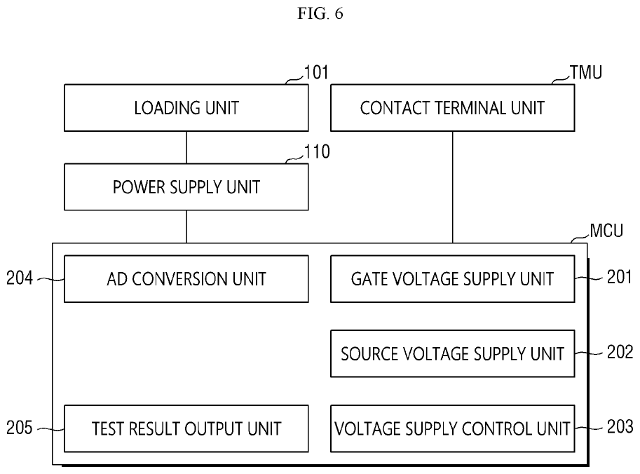

FIG. 5 is a configuration diagram illustrating a device for testing elements of a display panel and a process of testing a test panel according to one or more embodiments. FIG. 6 is a detailed block diagram illustrating each component of the device for testing elements of a display panel according to one or more embodiments.

Referring to FIGS. 5 and 6, a display panel DP and a test panel TP extending from the display panel DP are loaded on the element test device.

The element test device supplies driving voltages to thin-film transistors Tr of the test panel TP, and detects amounts of output current of the thin-film transistors Tr. To this end, the element test device includes a loader (e.g., loading unit) 101, a power supply 110, a contact terminal unit TMU having a plurality of contact terminals Tm, and a test signal processor (e.g., test-signal-processing unit) MCU.

The loader 101 may be formed in the form of a plate on which the display panel DP, and the test panel TP extending from the display panel DP, are loaded. The loader 101 fixes at least any one side of the display panel DP or the test panel TP loaded on the plate.

The power supply 110 generates driving voltages to be supplied to the thin-film transistors Tr of the test panel TP. For example, the power supply 110 may generate direct current (DC) and alternating current (AC) driving voltages to be supplied to the display panel DP or the test panel TP. In addition, the power supply 110 generates a first driving voltage to be supplied to first electrodes SE of the thin-film transistors Tr formed on the test panel TP, a second driving voltage to be supplied to second electrodes GE of the thin-film transistors Tr, and a third driving voltage to be supplied to third electrodes DE of the thin-film transistors Tr.

The contact terminal unit TMU includes a plurality of contact terminals Tm respectively contacting electrodes of the thin-film transistors Tr formed on the test panel TP, that is, the first electrodes SE, the second electrodes GE and the third electrodes DE of the thin-film transistors Tr. For example, a plurality of first electrode contact terminals among the contact terminals Tm may contact the first electrodes SE of first through fourth thin-film transistors Tr, respectively. In addition, a plurality of second electrode contact terminals among the contact terminals Tm may contact the second electrodes GE of the first through fourth thin-film transistors Tr, respectively. On the other hand, a plurality of third electrode contact terminals among the contact terminals Tm may contact the third electrodes DE of the first through fourth thin-film transistors Tr, respectively.

In an example in which electrical characteristics of every first through fourth thin-film transistors Tr arranged side by side on the test panel TP are concurrently or substantially simultaneously detected, the contact terminal unit TMU may include a plurality of contact terminals Tm respectively contacting the first electrodes SE, the second electrodes GE, and the third electrodes DE of every first through fourth thin-film transistors Tr among the thin-film transistors Tr formed on the test panel TP. Here, the first electrode SE of each of the thin-film transistors Tr may be a source electrode, the second electrode GE may be a gate electrode, and the third electrode DE may be a drain electrode.

The contact terminal unit TMU includes a first channel line connecting the first electrode contact terminals, which contact the first electrodes SE of the thin-film transistors Tr formed on the test panel TP, to one channel in a parallel structure. The contact terminal unit TMU also includes a second channel line connecting the second electrode contact terminals to another channel in a parallel structure. In addition, the contact terminal unit TMU further includes k channel lines connecting the third electrode contact terminals to k other channels in a one-to-one manner. Here, k is the same number as the number of thin-film transistors Tr concurrently or substantially simultaneously contacted by the third electrode contact terminals. A first driving signal may be concurrently or substantially simultaneously supplied to the first electrodes SE of the thin-film transistors Tr through one first channel line. In addition, a second driving signal may be concurrently or substantially simultaneously supplied to the second electrodes GE of the thin-film transistors Tr through one second channel line. Output currents respectively output from the third electrodes DE of the thin-film transistors Tr may be transmitted to the test signal processor MCU through the k channel lines, respectively.

The test signal processor MCU may include a gate voltage supply (e.g., gate voltage supply unit) 201, a source voltage supply (e.g., source voltage supply unit) 202, a voltage supply control (e.g., voltage supply control unit) 203, an analog-digital (AD) converter (e.g., AD conversion unit) 204, and a test result output unit 205.

For example, the source voltage supply 202 may alternately generate a first driving voltage of about 0.1 V and a first driving voltage of about 5.1 V in different periods. Accordingly, the source voltage supply 202 may output the first driving voltage of about 0.1 V during a first period (e.g., preset first period) under the control of the voltage supply control 203. On the other hand, the source voltage supply 202 may output the first driving voltage of about 5.1 V during a second period (e.g., preset second period) under the control of the voltage supply control 203.

The gate voltage supply 201 may generate a second driving voltage that

gradually varies from about 8.0 V to about −13 V by about 0.25 V. Alternatively, the gate voltage supply 201 may generate a second driving voltage that gradually varies from about −15 V to about 15 V by about 0.25 V.

The voltage supply control 203 controls the source voltage supply 202 to output the first driving voltage of about 0.1 V to the first channel line during the first period (e.g., preset first period). In addition, the voltage supply control 203 may control the source voltage supply 202 to output the first driving voltage of about 5.1 V to the first channel line during the second period (e.g., preset second period). In addition, the voltage supply control 203 controls the gate voltage supply 201 to output the second driving voltage to the second channel line during the first and second periods.

The AD converter 204 receives output currents respectively output from the third electrodes DE of the thin-film transistors Tr through the k channel lines. The AD converter 204 filters the output currents respectively output from the third electrodes DE of the thin-film transistors Tr, and detects and converts current amounts and voltage levels.

The test result output unit 205 transmits information about the current amounts and voltage levels of the output currents respectively output from the third electrodes DE of the thin-film transistors Tr to an external display device, such as a monitor.

The test signal processor MCU concurrently or substantially simultaneously supplies the first driving voltage to the first electrodes SE of the first through fourth thin-film transistors Tr through the first channel line and the first electrode contact terminals among the contact terminals Tm formed in the contact terminal unit TMU.

In addition, the test signal processor MCU concurrently or substantially simultaneously supplies the second driving voltage to the second electrodes GE of the first through fourth thin-film transistors Tr through the second channel line and the second electrode contact terminals among the contact terminals Tm.

Also, the test signal processor MCU detects the output currents respectively output from the third electrodes DE of the first through fourth thin-film transistors Tr through the k channel lines and the third electrode contact terminals among the contact terminals Tm.

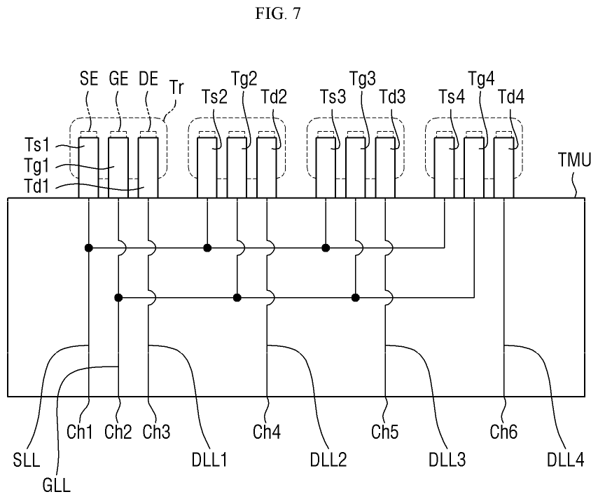

FIG. 7 is a configuration diagram illustrating, in detail, the channel contact structure of the contact terminal unit TMU illustrated in FIG. 6.

Referring to FIG. 7, the contact terminal unit TMU includes first electrode contact terminals Ts1, Ts2, Ts3, and Ts4, second electrode contact terminals Tg1, Tg2, Tg3, and Tg4, third electrode contact terminals Td1, Td2, Td3, and Td4, and first through kth channel lines SLL, GLL, DLL1, DLL2, DLL3 and DLL4.

The first electrode contact terminals Ts1 through Ts4 contact the first electrodes SE of the first through fourth thin-film transistors Tr, respectively.

The second electrode contact terminals Tg1 through Tg4 contact the second electrodes GE of the first through fourth thin-film transistors Tr, respectively.

The third electrode contact terminals Td1 through Td4 contact the third electrodes DE of the first through fourth thin-film transistors Tr, respectively.

The first channel line SLL is connected in a parallel structure between the first electrode contact terminals Ts1 through Ts4, which respectively contact the first electrodes SE of the first through fourth thin-film transistors Tr, and one first channel Ch1. The first channel line SLL allows the first electrode contact terminals Ts1 through Ts4 to be electrically connected to the test signal processor MCU through one first channel Ch1.

The second channel line GLL is connected in a parallel structure between the second electrode contact terminals Tg1 through Tg4, which respectively contact the second electrodes GE of the first through fourth thin-film transistors Tr, and one second channel Ch2. The second channel line GLL allows the second electrode contact terminals Tg1 through Tg4 to be electrically connected to the test signal processor MCU through one second channel Ch2.

The k channel lines DLL1 through DLL4 are connected one-to-one between the third electrode contact terminals Td1 through Td4, which respectively contact the third electrodes DE of the first through fourth thin-film transistors Tr, and k channels Ch3, Ch4, Ch5, and Ch6. The k channel lines DLL1 through DLL4 allow the third electrode contact terminals Td1 through Td4 to be electrically connected to the test signal processor MCU through the k channels Ch3 through Ch6.

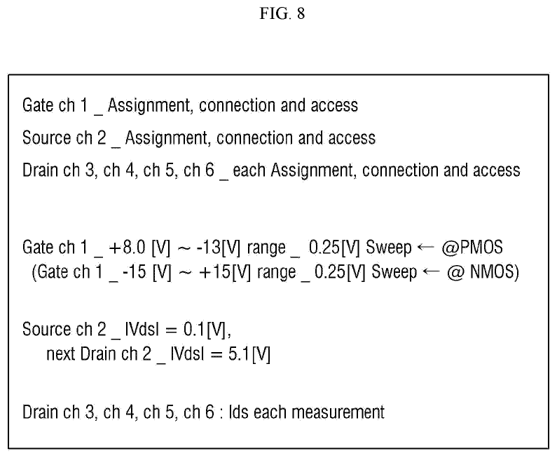

FIG. 8 is a monitoring screen showing a test panel testing sequence according to one or more embodiments.

Referring to FIG. 8, when a display panel DP, and a test panel TP extending from the display panel DP, are loaded and aligned on the loader 101 of the element test device, the first electrode contact terminals Ts1 through Ts4 of the contact terminal unit TMU contact the first electrodes SE of the first through fourth thin-film transistors Tr, respectively.

In addition, the second electrode contact terminals Tg1 through Tg4 contact the second electrodes GE of the first through fourth thin-film transistors Tr, respectively, and the third electrode contact terminals Td1 through Td4 contact the third electrodes DE of the first through fourth thin-film transistors Tr, respectively.

The test signal processor MCU concurrently or substantially simultaneously supplies a first driving voltage to the first electrodes SE of the first through fourth thin-film transistors Tr through the first channel line SLL and the first electrode contact terminals Ts1 through Ts4 formed in the contact terminal unit TMU.

The test signal processor MCU may concurrently or substantially simultaneously supply a first driving voltage of about 0.1 V to the first electrodes SE of the first through fourth thin-film transistors Tr through the first channel Ch1 during a first period (e.g., preset first period).

In addition, the test signal processor MCU may concurrently or substantially simultaneously supply a second driving voltage, which gradually varies from about 8.0 V to about −13 V by about 0.25 V, to the second electrodes GE of the first through fourth thin-film transistors Tr through the second channel Ch2 during the first period (e.g., preset first period).

When the first through fourth test thin-film transistors Tr formed on the test panel TP are of a PMOS type, the test signal processor MCU supplies a second driving voltage, which gradually varies from about 8.0 V to about −13 V by about 0.25 V, to the second electrodes GE of the first through fourth thin-film transistors Tr. In contrast, when the first through fourth test thin-film transistors Tr formed on the test panel TP are of an NMOS type, the test signal processor MCU may supply a second driving voltage, which gradually varies from about −15 V to about 15 V by about 0.25 V, to the second electrodes GE of the first through fourth thin-film transistors Tr.

During the first period in which the test signal processor MCU supplies the first driving voltage to the first electrodes SE of the first through fourth thin-film transistors Tr, and supplies the second driving voltage to the second electrodes GE of the first through fourth thin-film transistors Tr, the test signal processor MCU detects output currents respectively output from the third electrodes DE of the first through fourth thin-film transistors Tr through the k channel lines DLL1 through DLL4.

Then, the test signal processor MCU may concurrently or substantially simultaneously supply a first driving voltage of about 5.1 V to the first electrodes SE of the first through fourth thin-film transistors Tr through the first channel Ch1 during a second period (e.g., preset second period).

In addition, the test signal processor MCU may concurrently or substantially simultaneously supply a second driving voltage, which gradually varies from about 8.0 V to about −13 V by about 0.25 V, to the second electrodes GE of the first through fourth thin-film transistors Tr through the second channel Ch2 during the second period (e.g., preset second period).

When the first through fourth test thin-film transistors Tr formed on the test panel TP are of the PMOS type, the test signal processor MCU supplies a second driving voltage, which gradually varies from about 8.0 V to about −13 V by about 0.25 V, to the second electrodes GE of the first through fourth thin-film transistors Tr.

When the first through fourth test thin-film transistors Tr formed on the test panel TP are of the NMOS type, the test signal processor MCU may supply a second driving voltage, which gradually varies from about −15 V to about 15 V by about 0.25 V, to the second electrodes GE of the first through fourth thin-film transistors Tr.

During the second period in which the test signal processor MCU supplies the first driving voltage to the first electrodes SE of the first through fourth thin-film transistors Tr, and supplies the second driving voltage to the second electrodes GE of the first through fourth thin-film transistors Tr, the test signal processor MCU detects output currents respectively output from the third electrodes DE of the first through fourth thin-film transistors Tr through the k channel lines DLL1 through DLL4.

The output currents of the first through fourth thin-film transistors Tr detected through the k channel lines DLL1 through DLL4 may be displayed in real time on a separate monitor device through the test result output unit 205.

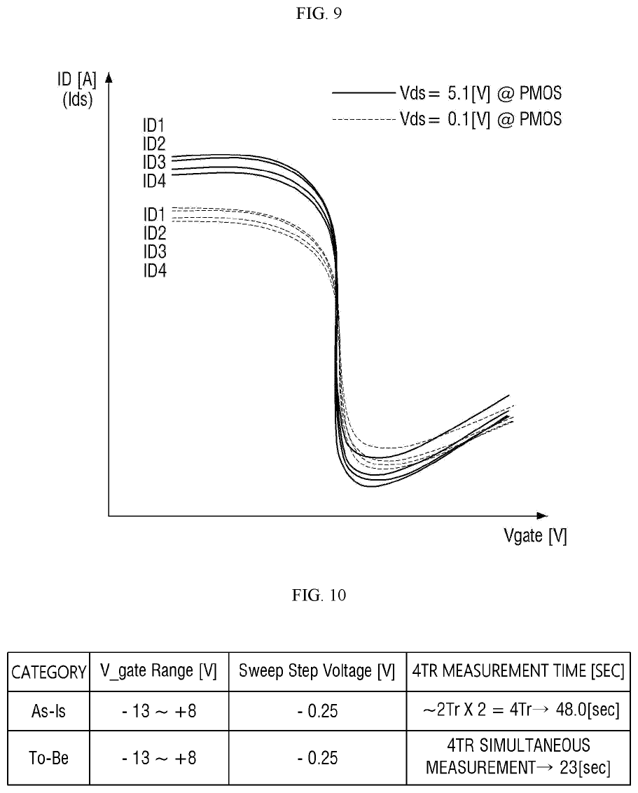

FIG. 9 is a graph illustrating the change in output current detected from thin-film transistors of a test panel.

Referring to FIG. 9, the test signal processor MCU supplies a first driving voltage of about 0.1 V to the first electrodes SE of the first through fourth thin-film transistors Tr, and supplies a second driving voltage, which gradually varies from about 8.0 V to about −13 V by about 0.25 V, to the second electrodes GE of the first through fourth thin-film transistors Tr during a first period.

During the first period, output currents ID1, ID2, ID3, and ID4, which are respectively output from the third electrodes DE of the first through fourth thin-film transistors Tr, are detected through the k channel lines DLL1 through DLL4. The output currents ID1 through ID4 respectively output from the third electrodes DE of the first through fourth thin-film transistors Tr vary according to a change in the second driving voltage during the first period.

The test signal processor MCU supplies a first driving voltage of about 5.1 V to the first electrodes SE of the first through fourth thin-film transistors Tr and supplies a second driving voltage, which gradually varies from about 8.0 V to about −13 V by about 0.25 V, to the second electrodes GE of the first through fourth thin-film transistors Tr during a second period.

During the second period, output currents ID1 through ID4, which are respectively output from the third electrodes DE of the first through fourth thin-film transistors Tr, are detected through the k channel lines DLL1 through DLL4. The output currents ID1 through ID4 respectively output from the third electrodes DE of the first through fourth thin-film transistors Tr vary according to a change in the second driving voltage during the second period.

FIG. 10 is a table showing a change in time suitable to test a test panel according to one or more embodiments.

Referring to FIG. 10, when first electrodes SE, second electrodes GE, and third electrodes DE of test thin-film transistors Tr are brought into contact with first through third electrode contact terminals to detect output currents of the test thin-film transistors Tr, three times as many electrode contact terminals, channels, and channel lines as the number of test thin-film transistors Tr might be suitable for operation. That is, electrode contact terminals, channels, and channel lines for supplying a first driving voltage and a second driving voltage to each test thin-film transistor Tr and for detecting an output current may be suitable for operation. The second driving voltage is supplied by gradually varying the second driving voltage from about 8.0 V to about −13 V or from about −13 V to about 8.0 V by about 0.25 V.

The output currents and electrical characteristics of every two test thin-film transistors Tr can be detected using six electrode contact terminals, six channels, and six channel lines. If the time suitable to detect the output currents of two test thin-film transistors Tr is about 24 seconds, the time suitable to detect the output currents of four test thin-film transistors Tr may be about 48 seconds.

On the other hand, the element test device according to one or more embodiments of the present disclosure can detect the output currents and electrical characteristics of four test thin-film transistors Tr at a time by using the contact terminal unit TMU having six channels Ch1 through Ch6. Therefore, the output currents of four test thin-film transistors Tr can be detected and checked during the same 24 second period as before.

As described above, the device for testing elements of a display panel according to one or more embodiments of the present disclosure can concurrently or substantially simultaneously detect and check electrical characteristics of a plurality of test elements, such as thin-film transistors Tr using a reduced (e.g., minimum) number of channels and electrode contact terminals. Accordingly, it is possible to relatively quickly test element characteristics of a test panel TP and a display panel DP, and to reduce the overall test period.

In addition, the device for testing elements of a display panel DP according to one or more embodiments concurrently or substantially simultaneously detects electrical characteristics of a plurality of test elements (e.g., thin-film transistors Tr) formed on a test panel TP in units of a group of four test elements. Therefore, the efficiency of testing the element characteristics of the display panel DP can be improved.

A device for testing elements of a display panel according to one or more embodiments of the present disclosure can concurrently or substantially simultaneously detect and check electrical characteristics of a plurality of test elements using a reduced (e.g., minimum) number of channels and connection pins. Accordingly, it is possible to quickly test element characteristics of a test panel and a display panel and reduce the overall test period.

In addition, the device for testing elements of a display panel according to one or more embodiments can improve the efficiency of testing element characteristics of a display panel by concurrently or substantially simultaneously detecting electrical characteristics of a plurality of test elements formed on a test panel on a group-by-group basis.

However, the aspects of the present disclosure are not restricted to the one set forth herein. The above and other aspects of the present disclosure will become more apparent to one of daily skill in the art to which the present disclosure pertains by referencing the claims, with functional equivalents thereof to be included therein.

In concluding the detailed description, those skilled in the art will appreciate that many variations and modifications can be made to the embodiments without substantially departing from the aspects of the present disclosure. Therefore, the disclosed embodiments of the disclosure are used in a generic and descriptive sense only and not for purposes of limitation.

What is claimed is:

1. An element test device comprising
a display panel on which electrical elements comprising thin-film transistors are located;
a test panel that extends from the display panel or is integral with the display panel, and on which test electrical elements are located through a same manufacturing process as the electrical elements; and
a test signal processor configured to substantially simultaneously supply a first driving voltage and a second driving voltage to the test electrical elements using a first channel and a second channel, respectively, and to detect electrical output characteristics of the test electrical elements using a number of k channels equal to a number of the test electrical elements.

2. The element test device of claim 1, further comprising:
a loader for receiving the display panel and the test panel;
a power supply configured to generate the first driving voltage and the second driving voltage to be supplied to the test electrical elements; and
a contact terminal unit comprising contact terminals respectively contacting first electrodes, second electrodes, and third electrodes of the test electrical elements.

3. The element test device of claim 2, wherein the test signal processor is configured to substantially simultaneously supply the first driving voltage to the first electrodes of the test electrical elements through a first channel line of the contact terminal unit, to substantially simultaneously supply the second driving voltage to the second electrodes of the test electrical elements through a second channel line of the contact terminal unit, and to detect electrical characteristics comprising voltages and current amounts of electrical signals respectively output from the third electrodes of the test electrical elements through k channel lines and the k channels of the contact terminal unit.

4. The element test device of claim 2, wherein the contact terminals comprise:
first electrode contact terminals respectively contacting the first electrodes of the test electrical elements;
second electrode contact terminals respectively contacting the second electrodes of the test electrical elements; and
third electrode contact terminals respectively contacting the third electrodes of the test electrical elements.

5. The element test device of claim 4, wherein the contact terminal unit further comprises:
a first channel line connecting the first electrode contact terminals to one first channel in a parallel structure;
a second channel line connecting the second electrode contact terminals to one second channel in a parallel structure; and
k channel lines connecting the third electrode contact terminals to the k channels in a one-to-one manner.

6. The element test device of claim 5, wherein the test signal processor, during a first period, is configured to supply the first driving voltage having a first voltage level to the first channel line, to supply the second driving voltage having a gradually varying voltage level to the second channel line, and to detect electrical signals respectively output from the third electrodes of the test electrical elements through the k channel lines, and, during a second period, is configured to supply the first driving voltage having a second voltage level that is different from the first voltage level to the first channel line, to supply the second driving voltage having a gradually varying voltage level to the second channel line, and to detect electrical signals respectively output from the third electrodes of the test electrical elements through the k channel lines.

7. The element test device of claim 6, wherein the test signal processor comprises:
a source voltage supply configured to alternately generate a first driving voltage of about 0.1 V and a first driving voltage of about 5.1 V during the first period and the second period, respectively;
a gate voltage supply configured to generate the second driving voltage that gradually varies from about 8.0 V to about −13 V by about 0.25 V, or that gradually varies from about −15 V to about 15V by about 0.25 V; and
a voltage supply control configured to control the source voltage supply to output the first driving voltage of about 0.1 V to the first channel line during the first period, to control the source voltage supply to output the first driving voltage of about 5.1 V to the first channel line during the second period, and to control the gate voltage supply to output the second driving voltage to the second channel line during the first period and the second period.

8. The element test device of claim 2, wherein the contact terminals comprise:
four first electrode contact terminals respectively contacting first electrodes of first through fourth thin-film transistors among the test electrical elements;
four second electrode contact terminals respectively contacting second electrodes of the first through fourth thin-film transistors; and
four third electrode contact terminals respectively contacting third electrodes of the first through fourth thin-film transistors.

9. The element test device of claim 8, wherein the contact terminal unit further comprises:
a first channel line connecting the four first electrode contact terminals to one first channel in a parallel structure;
a second channel line connecting the four second electrode contact terminals to one second channel in a parallel structure; and
k channel lines connecting the four third electrode contact terminals to the k channels in a one-to-one manner.

10. An element test device comprising:
a display panel on which electrical elements comprising thin-film transistors are located;
a test panel that extends from the display panel or is integral with the display panel, and on which test electrical elements are located through a same manufacturing process as the electrical elements;
a loader configured to receive the display panel and the test panel;
a power supply configured to generate a first driving voltage and a second driving voltage to be supplied to the test electrical elements;
a contact terminal unit comprising contact terminals respectively contacting first electrodes, second electrodes, and third electrodes of the test electrical elements; and
a test signal processor configured to substantially simultaneously supply the first driving voltage and the second driving voltage to the test electrical elements using a first channel and a second channel, respectively, and to detect electrical output characteristics of the test electrical elements using a number of k channels equal to the number of the test electrical elements.

11. The element test device of claim 10, wherein the test signal processor is configured to substantially simultaneously supply the first driving voltage to the first electrodes of the test electrical elements through a first channel line of the contact terminal unit, to substantially simultaneously supply the second driving voltage to the second electrodes of the test electrical elements through a second channel line of the contact terminal unit, and to detect electrical characteristics comprising voltages and current amounts of electrical signals respectively output from the third electrodes of the test electrical elements through k channel lines and the k channels of the contact terminal unit.

12. The element test device of claim 10, wherein the contact terminals comprise:
first electrode contact terminals respectively contacting the first electrodes of the test electrical elements;
second electrode contact terminals respectively contacting the second electrodes of the test electrical elements; and
third electrode contact terminals respectively contacting the third electrodes of the test electrical elements.

13. The element test device of claim 12, wherein the contact terminal unit further comprises:
a first channel line connecting the first electrode contact terminals to one first channel in a parallel structure;
a second channel line connecting the second electrode contact terminals to one second channel in a parallel structure; and
k channel lines connecting the third electrode contact terminals to the k channels in a one-to-one manner.

14. The element test device of claim 13, wherein the test signal processor, during a first period, is configured to supply the first driving voltage having a first voltage level to the first channel line, to supply the second driving voltage having a gradually varying voltage level to the second channel line, and to detect electrical signals respectively output from the third electrodes of the test electrical elements through the k channel lines, and, during a second period, is configured to supply the first driving voltage having a second voltage level that is different from the first voltage level to the first channel line, to supply the second driving voltage having a gradually varying voltage level to the second channel line, and to detect electrical signals respectively output from the third electrodes of the test electrical elements through the k channel lines.

15. The element test device of claim 10, wherein the contact terminals comprise:
four first electrode contact terminals respectively contacting first electrodes of first through fourth thin-film transistors among the test electrical elements;
four second electrode contact terminals respectively contacting second electrodes of the first through fourth thin-film transistors; and
four third electrode contact terminals respectively contacting third electrodes of the first through fourth thin-film transistors.

16. The element test device of claim 15, wherein the contact terminal unit further comprises:
a first channel line connecting the four first electrode contact terminals to one first channel in a parallel structure;
a second channel line connecting the four second electrode contact terminals to one second channel in a parallel structure; and
k channel lines connecting the four third electrode contact terminals to the k channels in a one-to-one manner.
